(19) United States
(12) Patent Application Publication
(10) Pub. No.: US 2024/0175352 A1
(43) Pub. Date: May 30, 2024

(54) Predicting Reservoir Quality

(71) Applicant: Saudi Arabian Oil Company, Dhahran (SA)

(72) Inventors: Peng Lu, Dhahran (SA); Rainer Zuhlke, Dhahran (SA)

(21) Appl. No.: 18/070,023

(22) Filed: Nov. 28, 2022

(51) Int. Cl. E21B 49/00; G06F 30/20

(52) U.S. Cl. CPC E21B 49/00; G06F 30/20; E21B 2200/20

(57) ABSTRACT

Systems and methods of predicting reservoir quality can include measuring properties of a subsurface reservoir. Based on the measured properties of the subsurface reservoir; a modeling grid and domain representing a sediment textural framework of a subsurface reservoir are initialized. Deposition of sediments during the time period is predicted using a depositional model. The modeling grid and domain are updated based on the predicted deposition. The modeling grid and domain is transferred from the depositional model to a diagenetic model. The sediment textural framework of the area's subsurface is updated using the diagenetic model to simulate physical and chemical changes to deposited sediments during the time period. The modeling grid and domain is stored and a test well can be drilled based on the modeling grid and domain.

### TECHNICAL FIELD

The present disclosure generally relates to predicting reservoir quality, particularly predicting reservoir quality using paired diagenetic and sedimentary models.

### BACKGROUND

A carbonate platform is a sedimentary body which possesses topographic relief, and is composed of autochthonic calcareous deposits. Platform growth is mediated by sessile organisms whose skeletons build up the reef or by organisms which induce carbonate precipitation through their metabolism.

Several factors influence the depositional profile of a carbonate platform, including inherited topography, synsedimentary tectonics, exposure to currents and trade winds. An important factor influencing depositional profile is the type of carbonate factory. A carbonate factory is the ensemble of the sedimentary environment, the intervening organisms and the precipitation processes that lead to the formation of a carbonate platform. One example of carbonate factories are cool-water factories, which produce carbonate platforms that demonstrate three parts: the inner ramp (area above the fair-weather wave base), the middle ramp (area between the fair-weather wave base and the storm wave base), and the outer ramp (area below the storm wave base). In distally steepened ramps, a distal step is formed between the middle and outer ramp, by the in-situ accumulation of gravel-sized carbonate grains only episodically moved by currents. Carbonate production occurs along the full depositional profile in this type of carbonate platforms, with an extra production in the outer part of the middle ramp.

After deposition of sediments, a carbonate platform might undergo diagenesis. Diagenesis is the process that describes physical and chemical changes in sediments first caused by water-rock interactions, microbial activity, and compaction after their deposition. The study of diagenesis in rocks is used to aid in assessing the likelihood of finding various economically viable mineral and hydrocarbon deposits. For hydrocarbon reservoirs, these water-rock interactions can have a significant effect on the original (depositional, textural) reservoir quality framework of carbonate rock types, and will either create, modify, or destroy reservoir quality. For example, carbonate dissolution due to the influx of rain water or acidic fluid may create the porosity and enhance the permeability of the rock. Dolomitization, the process of altering limestone to dolomite, will not only induce the mineralogy changes (calcite changed to dolomite), but also the rock texture and pore structures and thus modify the porosity and permeability. The formation of carbonate cementation will occupy the pore spaces and will reduce or even destroy the porosity and permeability.

### SUMMARY

This specification describes systems and methods that address the coupling of depositional and diagenetic processes by using process-based depositional and diagenetic modeling and integrating both modeling. These systems and methods use a reactive transport modeling approach, which simulates the reactions of gas, fluid flow and rock (minerals) founded on rigorous thermodynamic and chemical kinetic theory, for diagenetic modeling. In some approaches, this is done in pseudo-real time In reality, depositional and diagenetic processes happen at the same time. However, due to the limitation of the software/approach, they can only be simulated one-by-one and alternating each other to represents the actual situation.

An iterative approach is used to couple depositional and diagenetic modeling at pseudo real-time in order to characterize the early carbonate deposition and diagenesis. The iterative approach is realized by the discretization of deposition and diagenesis modeling into a sequence of small-time steps and sequential alternation of the two modeling approaches. Six orders of sea level cycles have been recognized from stratigraphic evidence. Generally, this approach targets the fifth- to sixth-order sequence with time range of 1,000 to 10,000 yr and thickness range of 0.1-1 m. The method uses depositional modeling to establish the initial sediment textural framework at the time of deposition, and diagenetic modeling to quantify and predict various diagenetic modifications that significantly affect initial carbonate rock properties (e.g., hydrocarbon reservoir rocks). The sediment stack is subdivided into thin individual layers (deposited during short-term time intervals) and diagenetic modeling (e.g., reactive transport modeling) is run after depositional modeling for each layer. For example, time steps of between 1 and 10 thousand years (k.y.) are typically associated with layers of between 0.1 and 1 meters (m). The results of diagenetic modeling are then integrated back on the depositional modeling result of the same layer. The combined results for the two modeling approaches (e.g., thickness, porosity, permeability, density, seismic velocity and various well log response types) are then integrated for the subsequent time step of depositional and diagenetic modeling. In this way, the diagenesis process can be coupled with sediment deposition in a high-resolution sequential fashion at pseudo-real time, provided time steps selected are sufficiently short-term.

Carbonate facies are commonly the product of processes that are active in their depositional setting, such as water depth, winds, waves, currents, temperature, water chemistry, and biologic action. Facies also have significant impact on diagenesis (carbonate cementation in this case). The controls on the cementation rate in the sediments are broadly categorized into two groups: the reaction kinetics of the carbonate cement mineral (calcite or aragonite) and the transport of chemical solutes. For example, the location of the sediments in the platform will determine the effective flow velocity (and/or current) that transport the chemical solutes to the sites for precipitation. For the reaction kinetics, facies determines the intrinsic parameters such as grain size (reactive surface area), porosity and permeability, which affects the rates of cement precipitation.

This specification presents the iterative approach in an example of early carbonate cementation processes in a shallow marine carbonate ramp. The integrated model includes a simplified depositional model of a single shoaling-upward parasequence set (macrocycle) in carbonate shoal to middle ramp areas, built by five individual carbonate cycles (microcycles). The final model predicts the time-series of carbonate rock parameters. For demonstration purposes, the proportion of marine cements and porosity in different lithofacies has been selected as rock property. Modeling results are confirmed by real-world observations (e.g., petrographic data).

In one aspect, methods and systems of predicting carbonate reservoir quality include measuring properties of a subsurface reservoir (optionally) and initializing a modeling grid and domain representing a sediment textural framework of the subsurface reservoir based on the measured properties. For a time period, predicting deposition of sediments during the time period using a depositional model; updating the modeling grid and domain based on the predicted deposition; transferring the modeling grid and domain from the depositional model to a diagenetic model; and updating the sediment textural framework of the subsurface reservoir using the diagenetic model to simulate physical and chemical changes to deposited sediments during the time period. While additional layers of the subsurface reservoir remain to be incorporated into the modeling grid and domain, updating the time period and repeating the predicting deposition, updating the modeling grid and domain, transferring the modeling grid and domain, and updating the sediment textural framework steps; and optionally drilling a test well based on the modeling grid and domain. These systems and methods can include one or more of the following features.

In some embodiments, the subsurface reservoir comprises a plurality of sedimentary layers. In some cases, the time period is associated with one of the plurality of sedimentary layers and is less than 10,000 years. In some cases, the subsurface reservoir comprises a marine carbonate ramp.

In some embodiments, the diagenetic model is carbonate facies-dependent.

In some embodiments, the diagenetic model incorporates reactive transport modeling.

In some embodiments, the modeling grid and domain describe thickness, porosity, permeability, density, and/or seismic velocity of the layers of the subsurface reservoir.

Because carbonate depositional and early diagenetic processes occur concurrently or at similar time, and interact in terms of pore fluids, compaction and resulting porosity, the depositional and diagenetic processes can to be modeled using an integrated approach. Coupled depositional and diagenetic processes have been modeled within a depositional modeling framework in past studies. This specification describes a process-based modeling based on fundamental geological processes. This process-based modeling can be upscaled and downscaled (reservoir-field-basin) and applied to other fields than the traditional statistical-based or rule-based depositional and diagenetic modeling. In addition, this approach needs less well control for a modeled reservoir/field than traditional statistical-based or rule-based depositional and diagenetic modeling which conducted and completed depositional modeling of the entire carbonate stratigraphic series of interest and then superimposed the results from subsequently performed rule-based models or diagenetic modeling for the same entire stratigraphic series. However, during early carbonate diagenesis, depositional and diagenetic processes mutually affect each other, and the synergy effects are cumulative at small time scales. The approach described in this specification solves the challenge of reflecting the cumulative synergy effects of early carbonate sedimentation and diagenesis.

The details of one or more embodiments of these systems and methods are set forth in the accompanying drawings and the description below. Other features, objects, and advantages of these systems and methods will be apparent from the description and drawings, and from the claims.

### DESCRIPTION OF DRAWINGS

FIG. 1 illustrates an idealized depositional model of a tropical carbonate ramp.

FIG. 2 illustrates a method for predicting carbonate reservoir quality.

FIG. 3 includes plots representing a simplified depositional model with shoal and upper middle ramp depositional environments and their facies associations.

FIG. 4 includes plots of representing modeling domain and time-series textural lithofacies distribution for the typical shoaling upward parasequence set.

FIG. 5 includes plots of marine carbonate cement distribution (%) on the carbonate ramp generated using the method of FIG. 2.

FIG. 6 is a chart comparing modeled average marine cement percentage with the results from point counting analysis on specific lithofacies and lithotexture groups.

FIG. 7 is a block diagram illustrating an example computer system used to provide computational functionalities associated with described algorithms, methods, functions, processes, flows, and procedures according to some implementations of the present disclosure.

Like reference symbols in the various drawings indicate like elements.

### DETAILED DESCRIPTION

This specification provides systems and methods that address the coupling of depositional and diagenetic processes by using process-based depositional and diagenetic modeling and integrating both modeling.

Hydrocarbon reservoir quality is controlled by geological processes, which include both depositional processes and syn- to post-depositional modifications. Compared to clastics, carbonates are especially susceptible to diagenetic modifications due to the high chemical reactivity of carbonate minerals. These rock-water interactions can have a significant effect on the original (depositional, textural) reservoir quality framework of carbonate rock types, and will either create, modify, or destroy reservoir quality.

Because carbonate depositional and early diagenetic processes occur concurrently or at similar time, and interact in terms of pore fluids, compaction and resulting porosity, the depositional and diagenetic processes need to be modeled using an integrated approach. Coupled depositional and diagenetic processes have been modeled within a depositional modeling framework in past studies. The system and methods described in this specification use a process-based modeling approached based on fundamental geological processes rather than describing early cementation by applying simplified diagenetic rules. These systems and methods can be upscaled and downscaled (reservoir-field-basin) and applied to other fields, and need less well control for a modeled reservoir/field.

In some implementations, the reactive transport modeling approach used for diagenetic modeling simulates the reactions of gas, fluid flow and rock (minerals) founded on rigorous thermodynamic and chemical kinetic theory. Reactive transport modeling simulates the reaction of seawater with minerals (calcite/aragonite) in carbonate sediment at each current and all previously deposited and diagenetically altered microcycles. The simulated fluid flow supplies, circulates, or removes the solutes (dissolved solids) to facilitate the chemical reactions between the seawater and sediments. Dissolution reactions remove some materials from the existing carbonate grains and create secondary porosity, while precipitation reactions add new materials to the existing carbonate grains (overgrowth) and reduce the original porosity.

In some implementations, a similar workflow may be applied to investigate other early carbonate diagenesis processes, for example, erosion and dissolution, karsting associated with unconformities, cementation in specific diagenetic zones (vadose, meteoric phreatic, mixing, marine phreatic) and reflux dolomitization (ephemeral evaporative ponds or partly restricted areas will determine the rate and the extent of reflux dolomitization).

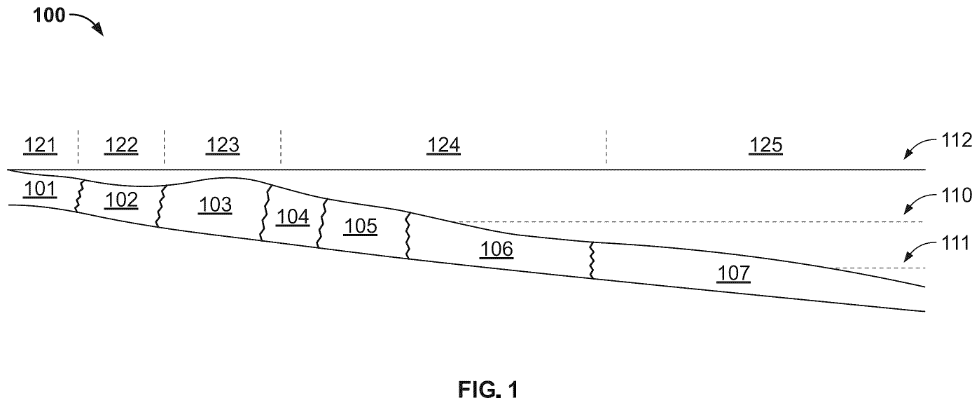

FIG. 1 illustrates an idealized depositional model of a tropical carbonate ramp 100. The model 100 is a homoclinal and distally steepened carbonate ramp on a continental shelf, which incorporates inner ramp (tidal flat 121 and lagoon 122), shoal 123, middle ramp 124, and outer ramp environments 125. Typical carbonate lithofacies in this example are: (i) anhydrite and gypsum facies 101 in the tidal flat 121; (ii) bioclastic packstone and wackestone 102 in the lagoon 122; (iii) oolitic-bioclastic grainstone and packstone (SO) 103 in shoal areas 123; (iv) bioturbated rudstone and floatstone (BT) 104, coral-algal reef complex (REEF) 105 and bioclastic rudstone 106 in the middle ramp 124; (v) mudstone and bioclastic wackestone 107 in the outer ramp 125. The depth of the fair-weather wave base (FWWB) 110 is set to 10 m, the storm wave base (SWB) 111 to 30 m. This figure, which is based on ramp settings recognized on Mesozoic shelves in many subsurface basins and outcrops, shows an overall shallowing-upward, prograding trend toward a shelf-interior basin with water depths of approximately 100 m. From a hydrocarbon exploration perspective, shoals are supposed to have experienced significant marine cementation but often still provide the best reservoir quality.

The model 100 represents a parasequence set in which the single macrocycle represents approximately 35 k.y. duration and each of the five (5) individual microcycles included represents approximately 7 k.y. The model focuses on the primary facies that occur in the SO 103, BT 104, and REEF 105 areas.

The model 100 had initial dimensions of 2,400 m in length (L)×12 m in height (H). The amplitude of sea level change during each microcycle is set to 0.6 m based on cycle thicknesses, following the assumption that accommodation space is filled to comparable water depths at the end of each microcycle and that the total amplitude of sea-level change reached 25-30 m over longer time-scales. The accommodation space generated from subsidence was 25-40 m per 0.35 m.y. and 30 m per 0.35 m.y. or 3 m per 35 k.y. was used in this study.

For simplicity, the model only considered a continuous sea-level fall and subsidence setting in a Highstand Systems Tract (HST) and Falling-Stage Systems Tract (FSST)/early Lowstand Systems Tract (LST) scenario. During a third-order sea level change, cycle amplitude is great enough (approximately 50-150 ft) to expose the shelf. Depositional sites range from coastal plain to deep basin. The unit of strata deposited during a third-order cycle is called a depositional sequence. A depositional sequence has three subdivisions: highstand systems tract (HST), transgressive systems tract (TST), and lowstand systems tract (LST). The initial transgressive part of each cycle was ignored, as it only accounts for a small fraction of each cycle or is not represented by deposition at all (lag-time of carbonate deposition). Progradational and aggradational stacking patterns are the dominant features for macrocycles in this carbonate ramp. Microcycles or more commonly macrocycles represent individual flow or reservoir units from an exploration perspective.

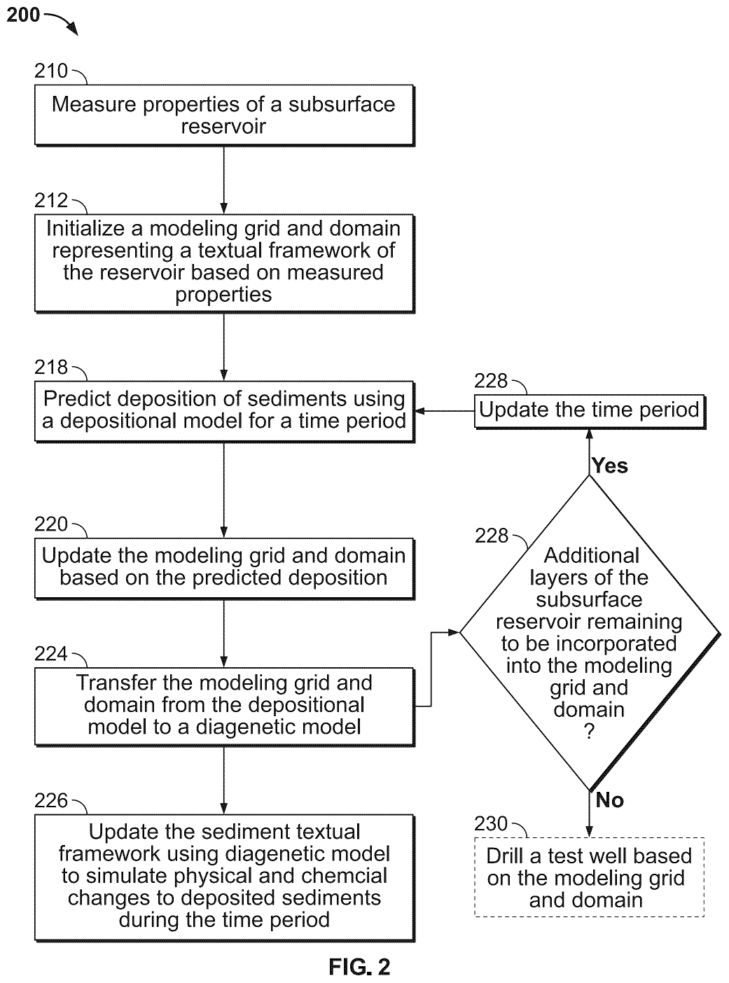

FIG. 2 illustrates a method 200 for predicting carbonate reservoir quality. The method 200 includes measuring properties of a subsurface reservoir 210, initializing a modeling grid and domain representing a textual framework of the reservoir based on the measured properties 212, predicting deposition of sediments using a depositional model 218 for a given time period, updating the modeling grid and domain based on the predicted deposition 220, transferring the modeling grid and domain from the depositional model to a diagenetic model 224, and updating the sediment textual framework using diagenetic model to simulate physical and chemical changes to deposited sediments during the time period 226. If additional layers of the subsurface reservoir remain to be incorporated into the modeling grid and domain 228, the time period is updated 228, and the predicting 218, the updating 220, the transferring 224, and the second updating 226 steps are repeated. If there are no other additional layers to be incorporated 228, some implementations optionally include drilling a test well based on the modeling grid and domain 230.

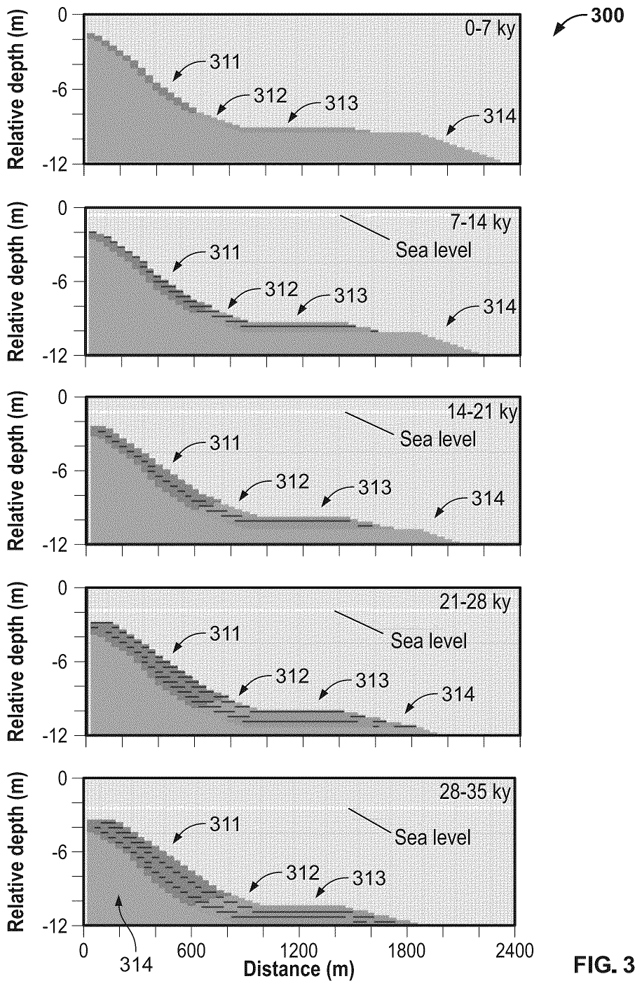

FIG. 3 includes plots representing a simplified depositional model with shoal and upper middle ramp depositional environments and their facies associations in representative shoaling upward parasequence sets (35 k.y.), with SO 311, BT 312, REEF 313, and platform interior 314. From the top down, the plots represent depositional environments from 0-7 k.y. 7-14 k.y. 14-21 k.y. 21-28 k.y. and 28-35 k.y.

The platform interior 314 contains sediments that have almost no cementation and mudstone is used to represent it. A single facies may be composed of more than one sediment type. For example, SO may include grainstone and mud-lean packstone. Subsequent diagenetic modeling uses the ramp geometry, stratigraphy and lithofacies distribution obtained from the depositional model. The plots illustrate the movement and increase in thickness of the layers of interest. FIG. 3 also shows two dynamic changes: sea level drop and subsidence (of the platform). Sea level drop during each microcycle (7 k.y.) is set to 0.6 m. The platform subsidence is also 0.6 m per microcycle (7 k.y.).

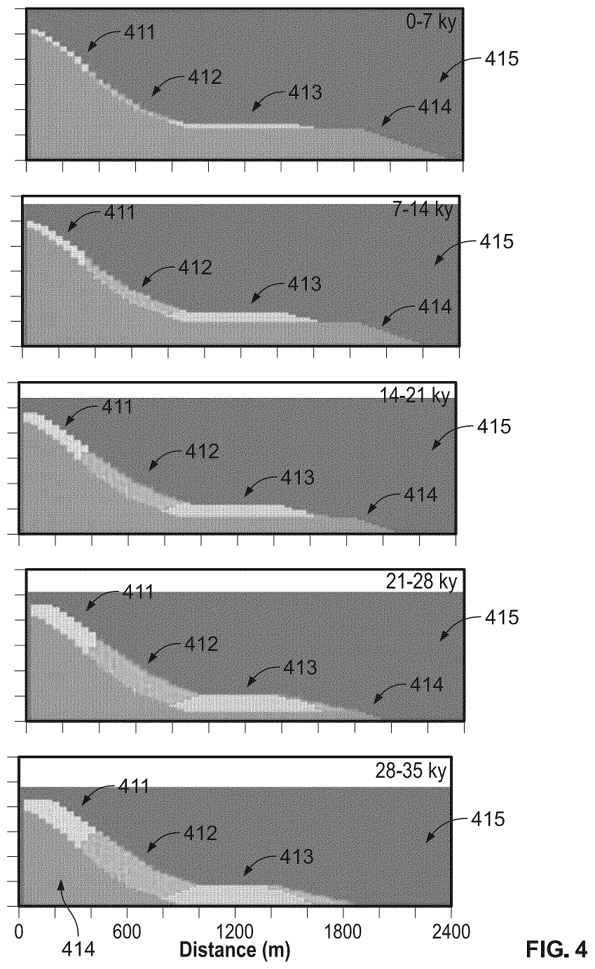

FIG. 4 includes plots of representing modeling domain and time-series textural lithofacies distribution for the typical shoaling upward parasequence set. FIG. 4 represent a modeling domain and time-series textural lithofacies distribution for the typical shoaling upward parasequence set, with grainstone 411, mud-lean packstone 412, packstone 413, mudstone 414, seawater 415. The vertical exaggeration is 70. From the top down, the plots represent modeling domain and time-series textural lithofacies distribution from 0-7 k.y. 7-14 k.y. 14-21 k.y. 21-28 k.y. and 28-35 k.y. These modeling domain and time-series textural lithofacies distribution are provided to the diagenetic model as input. The iteration of passing the domain to the diagenetic model and running before passing back to depositional model take places every 7 k.y. This approach reflects that changes to the cements abundance and porosity are cumulative after each step. Similar to FIG. 3, there are two dynamic changes: sea level drop and subsidence (of the platform). Sea level drop during each microcycle (7 k.y.) is set to 0.6 m. The platform subsidence is also 0.6 m per microcycle (7 k.y.).

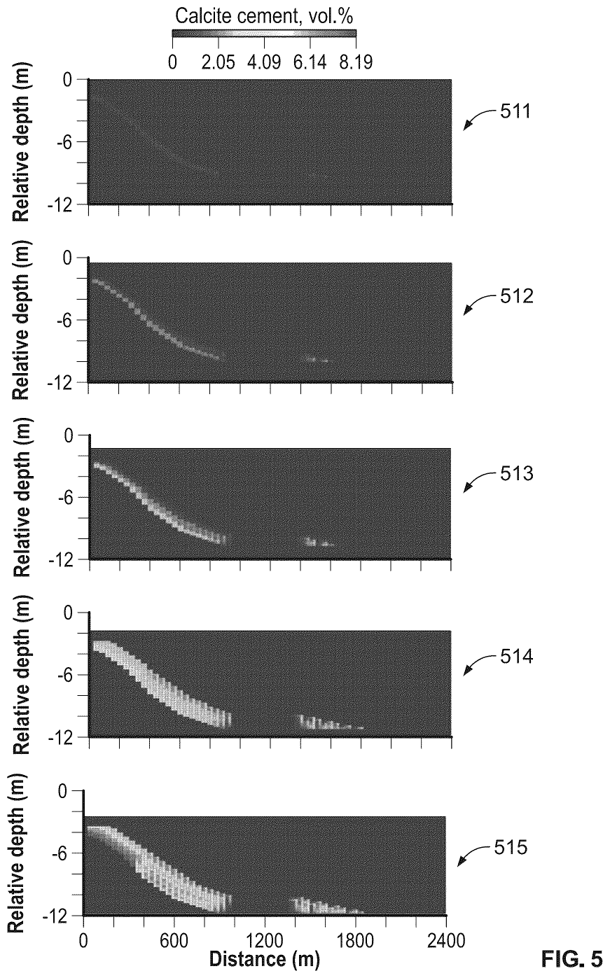

FIG. 5 includes plots of marine carbonate cement distribution (%) on the carbonate ramp generated using the method of FIG. 2. Vertical exaggeration is 70×. From the top down, the plots represent marine carbonate cement distribution results from the diagenetic model from 0-7 k.y. 7-14 k.y. 14-21 k.y. 21-28 k.y. and 28-35 k.y.

With the continuous deposition of additional carbonate sediment, marine carbonate cements grow in both the actively deposited layer as well as in pre-existing layers 300. Cement distribution depends on both depositional environment (essentially the location on the ramp) and textures of the hosting lithofacies. Calcite cement develops preferably in the shallower areas of the shoal environment 122 (SO facies) and the highest abundance of calcite cement occurs in the SO facies with grainstone texture. In the REEF 105 facies, a significant amount of cement develops near the sediment-water interface. There is almost no cement in the sheltered leeward areas.

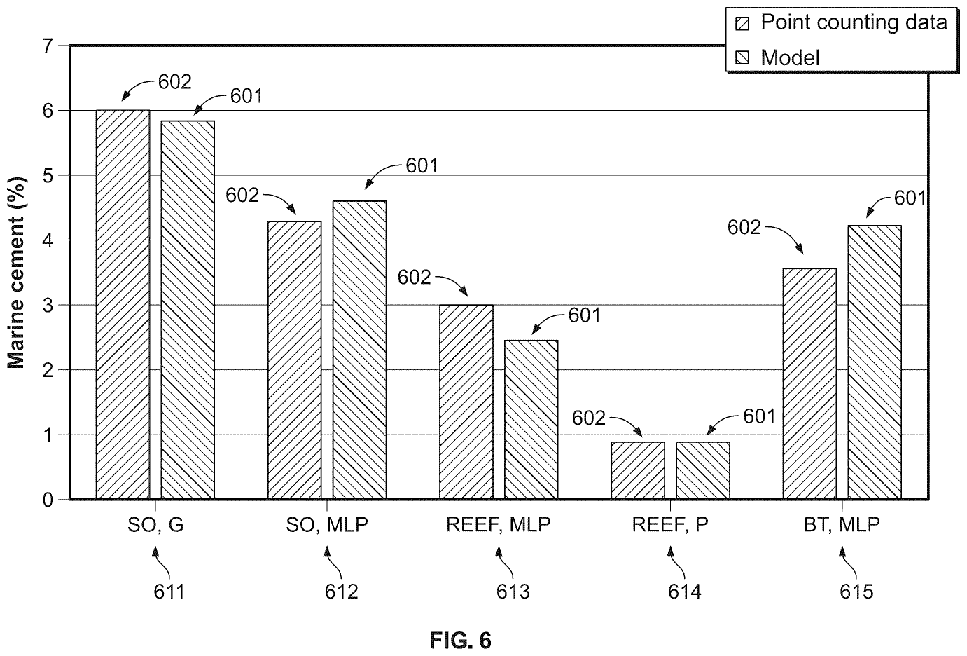

FIG. 6 is a chart comparing modeled average marine cement percentage 601 with the results from point counting 602 analysis on specific lithofacies and lithotexture groups, where SO,G 611 represents skeletal and oolitic grainstone, SO,MLP 612 represents skeletal and oolitic mud-lean packstone, REEF,MLP 613 represents coral-algal reef complex mud-lean packstone, REEF,P represents coral-algal reef complex packstone, and BT,MLP 615 represents bioturbated mud-lean packstone. Petrographic thin-sections for point counting analysis. Point counting is a means of describing rock in an unbiased and quantitative way. Between 400 and 600 points were counted along evenly spaced traverses across or down the length of all the thin sections. The procedure is based on principles and methods in standard textbooks on optical mineralogy and petrography. General principles are also outlined in ASTM-E 562 83, Standard Practice for Determining Volume Fraction by Systematic Manual Point Count. A database of 635 thin-section analysis was established for the reservoir of interest as a good representation of the carbonate cementation abundance as a function of facies and platform locations of the reservoir.

Cement abundances as a function of depositional facies and rock texture from the pseudo-coupled model is compared to real-world representative carbonate samples from a carbonate ramp. The petrographic thin section point counting data confirm the results of diagenetic modeling in this study FIG. 4. Generally, skeletal and oolitic grainstone 611 has the highest abundance of marine cements, followed by skeletal and oolitic mud-lean packstone 612, bioturbated mud-lean packstone 615, coral-algal reef complex mud-lean packstone and coral-algal reef complex packstone 613, in decreasing order. SO has most abundant marine cements in terms of facies and more marine cements are precipitated in grainy rocks (grainstone and mud-lean packstone).

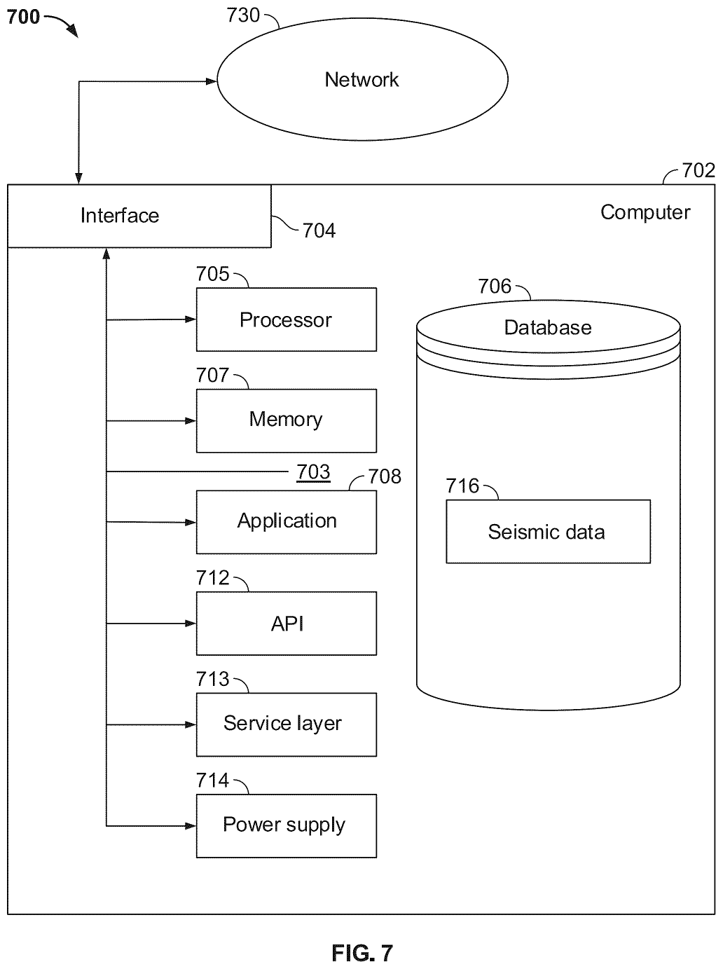

FIG. 7 is a block diagram of an example computer system 700 used to provide computational functionalities associated with described algorithms, methods, functions, processes, flows, and procedures described in the present disclosure, according to some implementations of the present disclosure. The illustrated computer 702 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 702 can include input devices such as keypads, keyboards, and touch screens that can accept user information. Also, the computer 702 can include output devices that can convey information associated with the operation of the computer 702. The information can include digital data, visual data, audio information, or a combination of information. The information can be presented in a graphical user interface (UI) (or GUI).

The computer 702 can serve in a role as a client, a network component, a server, a database, a persistency, or components of a computer system for performing the subject matter described in the present disclosure. The illustrated computer 702 is communicably coupled with a network 730. In some implementations, one or more components of the computer 702 can be configured to operate within different environments, including cloud-computing-based environments, local environments, global environments, and combinations of environments.

At a high level, the computer 702 is an electronic computing device operable to receive, transmit, process, store, and manage data and information associated with the described subject matter. According to some implementations, the computer 702 can also include, or be communicably coupled with, an application server, an email server, a web server, a caching server, a streaming data server, or a combination of servers.

The computer 702 can receive requests over network 730 from a client application (for example, executing on another computer 702). The computer 702 can respond to the received requests by processing the received requests using software applications. Requests can also be sent to the computer 702 from internal users (for example, from a command console), external (or third) parties, automated applications, entities, individuals, systems, and computers.

Each of the components of the computer 702 can communicate using a system bus 703. In some implementations, any or all of the components of the computer 702, including hardware or software components, can interface with each other or the interface 704 (or a combination of both), over the system bus 703. Interfaces can use an application programming interface (API) 712, a service layer 713, or a combination of the API 712 and service layer 713. The API 712 can include specifications for routines, data structures, and object classes. The API 712 can be either computer-language independent or dependent. The API 712 can refer to a complete interface, a single function, or a set of APIs.

The service layer 713 can provide software services to the computer 702 and other components (whether illustrated or not) that are communicably coupled to the computer 702. The functionality of the computer 702 can be accessible for all service consumers using this service layer. Software services, such as those provided by the service layer 713, can provide reusable, defined functionalities through a defined interface. For example, the interface can be software written in JAVA, C++, or a language providing data in extensible markup language (XML) format. While illustrated as an integrated component of the computer 702, in alternative implementations, the API 712 or the service layer 713 can be stand-alone components in relation to other components of the computer 702 and other components communicably coupled to the computer 702. Moreover, any or all parts of the API 712 or the service layer 713 can be implemented as child or sub-modules of another software module, enterprise application, or hardware module without departing from the scope of the present disclosure.

The computer 702 includes an interface 704. Although illustrated as a single interface 704 in FIG. 7, two or more interfaces 704 can be used according to particular needs, desires, or particular implementations of the computer 702 and the described functionality. The interface 704 can be used by the computer 702 for communicating with other systems that are connected to the network 730 (whether illustrated or not) in a distributed environment. Generally, the interface 704 can include, or be implemented using, logic encoded in software or hardware (or a combination of software and hardware) operable to communicate with the network 730. More specifically, the interface 704 can include software supporting one or more communication protocols associated with communications. As such, the network 730 or the interface's hardware can be operable to communicate physical signals within and outside of the illustrated computer 702.

The computer 702 includes a processor 705. Although illustrated as a single processor 705 in FIG. 7, two or more processors 705 can be used according to particular needs, desires, or particular implementations of the computer 702 and the described functionality. Generally, the processor 705 can execute instructions and can manipulate data to perform the operations of the computer 702, including operations using algorithms, methods, functions, processes, flows, and procedures as described in the present disclosure.

The computer 702 also includes a database 706 that can hold data for the computer 702 and other components connected to the network 730 (whether illustrated or not). For example, database 706 can be an in-memory, conventional, or a database storing data consistent with the present disclosure. In some implementations, database 706 can be a combination of two or more different database types (for example, hybrid in-memory and conventional databases) according to particular needs, desires, or particular implementations of the computer 702 and the described functionality. Although illustrated as a single database 706 in FIG. 7, two or more databases (of the same, different, or combination of types) can be used according to particular needs, desires, or particular implementations of the computer 702 and the described functionality. While database 706 is illustrated as an internal component of the computer 702, in alternative implementations, database 706 can be external to the computer 702.

The computer 702 also includes a memory 707 that can hold data for the computer 702 or a combination of components connected to the network 730 (whether illustrated or not). Memory 707 can store any data consistent with the present disclosure. In some implementations, memory 707 can be a combination of two or more different types of memory (for example, a combination of semiconductor and magnetic storage) according to particular needs, desires, or particular implementations of the computer 702 and the described functionality. Although illustrated as a single memory 707 in FIG. 7, two or more memories 707 (of the same, different, or combination of types) can be used according to particular needs, desires, or particular implementations of the computer 702 and the described functionality. While memory 707 is illustrated as an internal component of the computer 702, in alternative implementations, memory 707 can be external to the computer 702.

The application 708 can be an algorithmic software engine providing functionality according to particular needs, desires, or particular implementations of the computer 702 and the described functionality. For example, application 708 can serve as one or more components, modules, or applications. Further, although illustrated as a single application 708, the application 708 can be implemented as multiple applications 708 on the computer 702. In addition, although illustrated as internal to the computer 702, in alternative implementations, the application 708 can be external to the computer 702.

The computer 702 can also include a power supply 714. The power supply 714 can include a rechargeable or non-rechargeable battery that can be configured to be either user- or non-user-replaceable. In some implementations, the power supply 714 can include power-conversion and management circuits, including recharging, standby, and power management functionalities. In some implementations, the power-supply 714 can include a power plug to allow the computer 702 to be plugged into a wall socket or a power source to, for example, power the computer 702 or recharge a rechargeable battery.

There can be any number of computers 702 associated with, or external to, a computer system containing computer 702, with each computer 702 communicating over network 730. Further, the terms “client,” “user,” and other appropriate terminology can be used interchangeably, as appropriate, without departing from the scope of the present disclosure. Moreover, the present disclosure contemplates that many users can use one computer 702 and one user can use multiple computers 702.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

A number of embodiments of these systems and methods have been described. Nevertheless, it will be understood that various modifications may be made without departing from the spirit and scope of this disclosure. Accordingly, other embodiments are within the scope of the following claims.

What is claimed is:

1. A method of predicting carbonate reservoir quality, the method comprising:
measuring properties of a subsurface reservoir;
initializing a modeling grid and domain representing a sediment textural framework of the subsurface reservoir based on the measured properties;
for a time period,
predicting deposition of sediments during the time period using a depositional model;
updating the modeling grid and domain based on the predicted deposition;
transferring the modeling grid and domain from the depositional model to a diagenetic model;
updating the sediment textural framework of the subsurface reservoir using the diagenetic model to simulate physical and chemical changes to deposited sediments during the time period; and
while additional layers of the subsurface reservoir remain to be incorporated into the modeling grid and domain,
updating the time period and
repeating the predicting deposition, updating the modeling grid and domain, transferring the modeling grid and domain, and updating the sediment textural framework steps; and
drilling a test well based on the modeling grid and domain.

2. The method of claim 1, wherein the subsurface reservoir comprises a plurality of sedimentary layers.

3. The method of claim 2, wherein the time period is associated with one of the plurality of sedimentary layers and is less than 10,000 years.

4. The method of claim 2, wherein the subsurface reservoir comprises a marine carbonate ramp.

5. The method of claim 1, wherein the diagenetic model is carbonate facies-dependent.

6. The method of claim 1, wherein the diagenetic model incorporates reactive transport modeling.

7. The method of claim 1, wherein the modeling grid and domain describe thickness, porosity, permeability, density, and/or seismic velocity of the layers of the subsurface reservoir.

8. A system for predicting carbonate reservoir quality, the system comprising:
at least one processor; and
a memory storing instructions that, when executed by the at least one processor, cause the at least one processor to perform operations comprising:
measuring properties of a subsurface reservoir;
initializing a modeling grid and domain representing a sediment textural framework of the subsurface reservoir based on the measured properties;
for a time period,
predicting deposition of sediments during the time period using a depositional model;
updating the modeling grid and domain based on the predicted deposition;
transferring the modeling grid and domain from the depositional model to a diagenetic model;
updating the sediment textural framework of the subsurface reservoir using the diagenetic model to simulate physical and chemical changes to deposited sediments during the time period;
while additional layers of the subsurface reservoir remain to be incorporated into the modeling grid and domain,
updating the time period and
repeating the predicting deposition, updating the modeling grid and domain, transferring the modeling grid and domain, and updating the sediment textural framework steps.

9. The system of 8, wherein the time period is associated with one of the plurality of sedimentary layers and is less than 10,000 years.

10. The system of 8, wherein the diagenetic model is carbonate facies-dependent.

11. The system of 10, wherein the diagenetic model incorporates reactive transport modeling.

12. A method of predicting reservoir quality, the method comprising:
initializing a modeling grid and domain representing a sediment textural framework of a subsurface reservoir based on the measured properties of the subsurface reservoir;
for a time period,
predicting deposition of sediments during the time period using a depositional model;
updating the modeling grid and domain based on the predicted deposition;
transferring the modeling grid and domain from the depositional model to a diagenetic model;
updating the sediment textural framework of the area's subsurface using the diagenetic model to simulate physical and chemical changes to deposited sediments during the time period;
while additional layers of the area's subsurface remain to be incorporated into the modeling grid and domain,
updating the time period and
repeating the predicting deposition, updating the modeling grid and domain, transferring the modeling grid and domain, and updating the sediment textural framework steps; and
storing the modeling grid and domain.

13. The method of claim 12, wherein the subsurface reservoir comprises a plurality of sedimentary layers.

14. The method of claim 13, wherein the time period is associated with one of the plurality of sedimentary layers and is less than 10,000 years.

15. The method of claim 13, wherein the diagenetic model is carbonate facies-dependent.

16. The method of claim 15, wherein the diagenetic model incorporates reactive transport modeling.
